(19) United States
(12) Patent Application Publication
(10) Pub. No.: US 2009/0020816 A1
(43) Pub. Date: Jan. 22, 2009

(54) SEMICONDUCTOR DEVICE AND METHOD OF FORMING THE SAME

(75) Inventors: Woo-Jin CHO, Gyeonggi-do (KR); Yong-Woo LEE, Gyeonggi-do (KR); Jae-Seung HWANG, Gyeonggi-do (KR); Sung-Un KWON, Jeollabuk-do (KR); Min-Chul CHAE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/175,364

(22) Filed: Jul. 17, 2008

(30) Foreign Application Priority Data
Jul. 18, 2007 (KR) 2007-71789

(51) Int. Cl. H01L 29/00

(52) U.S. Cl. 257/347; 257/E29.001

(57) ABSTRACT

One embodiment generally described herein can be characterized as a semiconductor device. The semiconductor device can include a first transistor on a semiconductor substrate. A first interlayer insulating layer may be disposed over the first transistor and includes a first recess region. A single-crystalline semiconductor pattern may be disposed in the first recess region. A single-crystalline semiconductor plug may connect the semiconductor substrate to the single-crystalline semiconductor pattern. A second transistor may be disposed on the single-crystalline semiconductor pattern.

### CROSS-REFERENCE TO RELATED APPLICATIONS

This U.S. non-provisional patent application claims the benefit of foreign priority under 35 U.S.C. §119 to Korean Patent Application No. 2007-71789, filed on Jul. 18, 2007, the entire contents of which are herein incorporated by reference in their entirety.

### SUMMARY

Embodiments of the present invention disclosed herein generally relate to semiconductor devices, and more particularly, to a laminated semiconductor device and a method of forming the same.

One embodiment exemplarily described herein can be generally characterized as a semiconductor device that includes a first transistor on a semiconductor substrate; a first interlayer insulating layer covering the first transistor and including a first recess region; a single-crystalline semiconductor pattern disposed in the first recess region; a single-crystalline semiconductor plug connecting the semiconductor substrate to the single-crystalline semiconductor pattern; and a second transistor on the single-crystalline semiconductor pattern.

Another embodiment exemplarily described herein can be generally characterized as a semiconductor device that includes a first transistor on a semiconductor substrate, wherein the first transistor includes a first impurity region disposed in the semiconductor substrate; an interlayer insulating layer covering the first transistor; a plug disposed in the interlayer insulating layer, wherein a first end portion of the plug contacts the first impurity region; a single-crystalline semiconductor pattern contacting a second end portion of the plug, wherein at least a portion of the single-crystalline semiconductor pattern is below an upper surface of the interlayer insulating layer; and a second transistor on the single-crystalline semiconductor pattern, wherein the first transistor includes a first impurity region disposed in the single-crystalline semiconductor pattern.

### BRIEF DESCRIPTION OF THE FIGURES

The accompanying figures are included to provide a further understanding of embodiments of the present invention, and are incorporated in and constitute a part of this specification. The drawings illustrate exemplary embodiments of the present invention and, together with the description, serve to explain principles of the present invention. In the figures:

FIG. 1 is a cross sectional view of a laminated semiconductor device in accordance with a first embodiment of the present invention;

FIG. 2 is a cross sectional view of a laminated semiconductor device in accordance with a second embodiment of the present invention;

FIGS. 3 to 11 are cross sectional views illustrating a method of forming the laminated semiconductor device of FIG. 1, in accordance with one embodiment of the present invention;

FIGS. 12 to 14 are cross sectional views illustrating a method of forming the laminated semiconductor device of FIG. 1, in accordance with another embodiment of the present invention;

FIGS. 15 to 19 are cross sectional views illustrating a method of forming the laminated semiconductor device of FIG. 1, in accordance with still another embodiment of the present invention; and

FIGS. 20 and 21 are cross sectional views illustrating a method of forming the laminated semiconductor device of FIG. 2, in accordance with one embodiment of the present invention.

### DETAILED DESCRIPTION

Exemplary embodiments of the present invention now will be described more fully hereinafter with reference to the accompanying drawings. These embodiments may, however, be realized in many different forms and should not be construed as limited to the description set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention recited in the claims.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

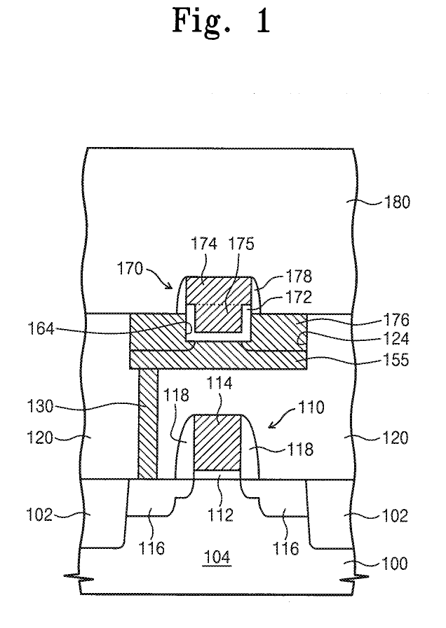

FIG. 1 is a cross sectional view of a laminated semiconductor device in accordance with a first embodiment of the present invention.

Referring to FIG. 1, a laminated semiconductor device in accordance with a first embodiment includes a first transistor 110 and a second transistor 170 that are arranged in an upper side and a lower side, respectively.

The first transistor 110 is disposed on a semiconductor substrate 100, and includes a first gate electrode 114 and first impurity regions 116. The semiconductor substrate 100 may, for example, be a single-crystalline silicon substrate and includes an active region 104 defined by a device isolation layer 102. A first gate insulating layer 112 and the first gate electrode 114 are sequentially stacked on the active region 104. The first impurity regions 116 are disposed in the active region 104 adjacent to both sides of the first gate electrode 114. In one embodiment, the first impurity regions 116 may have a lightly doped drain (LDD) structure. In another embodiment, the first impurity regions 116 may have a double diffused drain (DDD) structure. First spacers 118 are disposed on both sides of the first gate electrode 114.

A first interlayer insulating layer 120 including a first recess region 124 covers the first transistor 110. The first interlayer insulating layer 120 may, for example, be a single layer formed of one material. A single-crystalline semiconductor pattern 155 is disposed in the first recess region 124. The single-crystalline semiconductor pattern 155 may, for example, be a single-crystalline silicon pattern. The single-crystalline semiconductor pattern 155 is connected to the first impurity region 116 through a single-crystalline semiconductor plug 130 penetrating the first interlayer insulating layer 120. The single-crystalline semiconductor plug 130 may, for example, be a single-crystalline silicon plug. The single-crystalline semiconductor plug 130 may be epitaxially grown from the first impurity region 116. The single-crystalline semiconductor plug 130 may have substantially the same crystalline structure as the single-crystalline semiconductor pattern 155.

The second transistor 170 is disposed on the single-crystalline semiconductor pattern 155 and may include a second gate electrode 174 and second impurity regions 176. A second gate insulating layer 172 and the second gate electrode 174 are sequentially stacked on the single-crystalline semiconductor pattern 155. Second impurity regions 176 are disposed in the single-crystalline semiconductor pattern 155 adjacent to both sides of the second gate electrode 174. The second impurity regions 176 may have a lightly doped drain (LDD) structure or a double diffused drain (DDD) structure. Second spacers 178 are disposed on both sidewalls of the second gate electrode 174.

A second interlayer insulating layer 180 covering the second transistor 170 is disposed on the first interlayer insulating layer 120. An interface between the first interlayer insulating layer 120 and the second interlayer insulating layer 180 may have substantially the same height as an upper surface of the single-crystalline semiconductor pattern 155. Accordingly, an interface between the first interlayer insulating layer 120 and the second interlayer insulating layer 180 may be substantially coplanar with the upper surface of the single-crystalline semiconductor pattern 155.

In one embodiment, the upper surface of the single-crystalline semiconductor pattern 155 may have substantially the same height as an upper surface of the first interlayer insulating layer 120. That is, the upper surface of the single-crystalline semiconductor pattern 155 may be substantially coplanar with the upper surface of the first interlayer insulating layer 120. In another embodiment, the upper surface of the single-crystalline semiconductor pattern 155 may be lower than the upper surface of the first interlayer insulating layer 120. A second recess region 164 may be disposed within the single-crystalline semiconductor pattern 155. In one embodiment, the second recess region 164 may be disposed substantially at the center of the single-crystalline semiconductor pattern 155. The second gate electrode 174 may include a protrusion that is disposed within the second recess region 164. A cross-section of the protrusion may have an “I” or a “T” shaped configuration. The second gate insulating layer 172 may be interposed between the protrusion and the single-crystalline semiconductor pattern 155 exposed in the second recess region 164. That is, the second gate insulating layer 172 may be disposed along the surface of the single-crystalline semiconductor pattern 155 that is exposed in the second recess region 164. A cross-section of the second gate insulating layer 172 may have a “U” shaped configuration. Accordingly, the second transistor 170 of the first embodiment can be characterized as recess channel array transistor (RCAT). Because the second transistor 170 has an RCAT configuration, the second transistor 170 can suppress a short channel effect typically found in transistors that do not have an RCAT configuration.

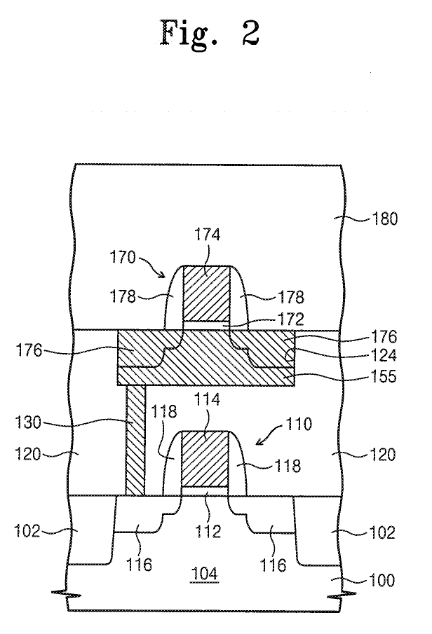

FIG. 2 is a cross sectional view of a laminated semiconductor device in accordance with a second embodiment of the present invention.

Referring to FIG. 2, a detailed description of features previous described with respect to the first embodiment are omitted for brevity. Generally, however, the illustrated laminated semiconductor device includes a first transistor 110 disposed on a semiconductor substrate 100 and a second transistor 170 disposed on a single-crystalline semiconductor pattern 155.

The first transistor 110 includes a first gate electrode 114 and first impurity regions 116. The second transistor 170 includes a second gate electrode 174 and second impurity regions 176. In one embodiment, the first impurity regions 116 and/or the second impurity regions 176 may have a lightly doped drain (LDD) structure. In another embodiment, the first impurity regions 116 and/or the second impurity regions 176 may have a double diffused drain (DDD) structure. First spacers 118 and second spacers 178 are disposed on both sides of the first gate electrode 114 and both sides of the second gate electrode 174, respectively.

A first interlayer insulating layer 120 including a recess region 124 covers the first transistor 110 and a single-crystalline semiconductor pattern 155 is disposed in the recess region 124. The first interlayer insulating layer 120 may, for example, be a single layer formed of one material. A second interlayer insulating layer 180 covering the second transistor is disposed on the first interlayer insulating layer 120. An interface between the first interlayer insulating layer 120 and the second interlayer insulating layer 180 may have substantially the same height as an upper surface of the single-crystalline semiconductor pattern 155. Accordingly, an interface between the first interlayer insulating layer 120 and the second interlayer insulating layer 180 may be substantially coplanar with the upper surface of the single-crystalline semiconductor pattern 155.

The single-crystalline semiconductor pattern 155 is connected to the first impurity region 116 through a single-crystalline semiconductor plug 130 penetrating the first interlayer insulating layer 120. The single-crystalline semiconductor plug 130 may be epitaxially grown from the first impurity region 116. The single-crystalline semiconductor plug 130 may have substantially the same crystalline structure as the single-crystalline semiconductor pattern 155.

In one embodiment, the upper surface of the single-crystalline semiconductor pattern 155 may have substantially the same height as an upper surface of the first interlayer insulating layer 120. That is, the upper surface of the single-crystalline semiconductor pattern 155 may be substantially coplanar with the upper surface of the first interlayer insulating layer 120. In another embodiment, the upper surface of the single-crystalline semiconductor pattern 155 may be lower than the upper surface of the first interlayer insulating layer 120. The single-crystalline semiconductor pattern 155 of second embodiment does not include a recess region. Therefore, the first and second transistors 110 and 170 may have the same or similar cross-sectional configurations.

Referring to FIGS. 3 to 11, a method of forming a laminated semiconductor device of FIG. 1, in accordance with one embodiment of the present invention will be described.

Referring to FIG. 3, a device isolation layer 102 that defines an active region 104 is formed in a semiconductor substrate 100. The semiconductor substrate 100 may, for example, be a single-crystalline silicon substrate. A first gate insulating layer 112 and a first gate electrode 114 are formed on the active region 104. The first gate insulating layer 112 may, for example, be formed of silicon oxide using a thermal oxidation process. The first gate electrode 114 may, for example, be formed of a doped polysilicon and/or metal using a chemical vapor deposition (CVD) process. First spacers 118 are formed on both sidewalls of the first gate electrode 114 and first impurity regions 116 are formed in the active region 104 adjacent to both sides of the first gate electrode 114. The first spacers 118 may, for example, be formed by forming an insulating layer (e.g., including a material such as silicon nitride material) on the semiconductor substrate 100 followed by anisotropically etching the insulating layer. The first impurity regions 116 may be formed to have a lightly doped drain (LDD) structure. For example, impurity regions 116 having an LDD structure may be formed by performing a first ion implantation process before forming the first spacers 118, to form low concentration impurity regions, followed by performing a second ion implantation process after forming the first spacers 118, to form high concentration impurity regions. The first gate electrode 114 and the first impurity regions 116 constitute the first transistor 110.

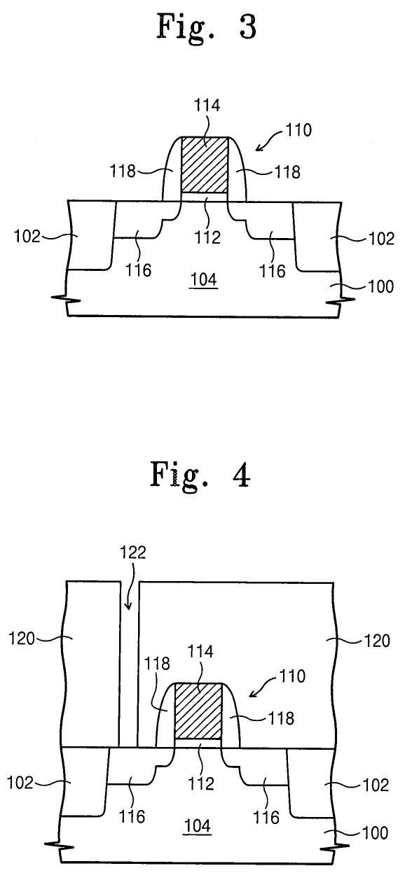

Referring to FIG. 4, a first interlayer insulating layer 120 is formed on the semiconductor substrate 100. The first interlayer insulating layer 120 may, for example, include a material such as oxide and be formed using a chemical vapor deposition (CVD) process. In one embodiment, the first interlayer insulating layer 120 may be a single layer formed of one material. The first interlayer insulating layer 120 may cover the first transistor 110. The first interlayer insulating layer 120 may be etched to form an opening 122 that exposes a first impurity region 116.

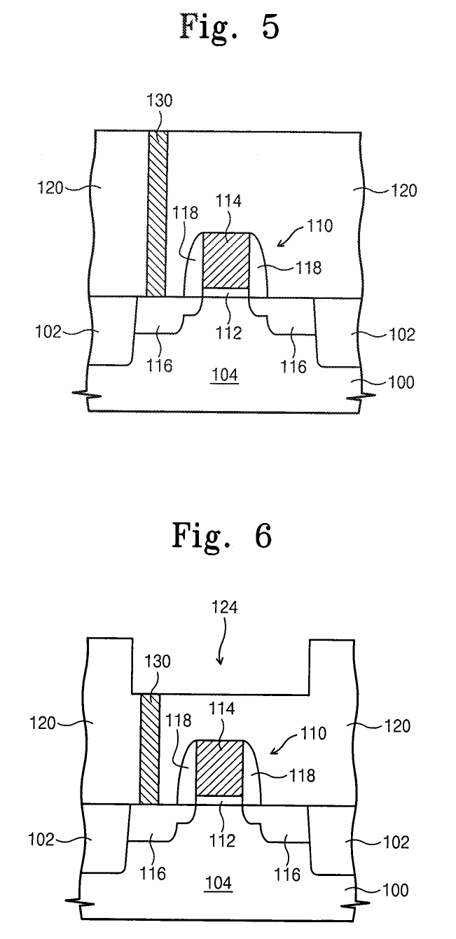

Referring to FIG. 5, a single-crystalline semiconductor plug 130 is formed in the opening 122. In one embodiment, the single-crystalline semiconductor plug 130 is epitaxially grown from the exposed first impurity regions 116. The single-crystalline semiconductor plug 130 may have the substantially the same crystalline structure as the semiconductor substrate 100. In one embodiment, the single-crystalline semiconductor plug 130 may, for example, be a single-crystalline silicon plug. After an epitaxial process is performed, a planarization process a chemical mechanical polishing (CMP) may, for example, be performed. An upper surface of the single-crystalline semiconductor plug 130 may have substantially the same height as an upper surface of the first interlayer insulating layer 120. That is, the upper surface of the single-crystalline semiconductor plug 130 may by substantially coplanar with the upper surface of the first interlayer insulating layer 120.

Referring to FIG. 6, a portion of the first interlayer insulating layer 120 on the first transistor 110 is etched to form a first recess region 124. In one embodiment, an upper portion of the single-crystalline semiconductor plug 130 may be etched to have substantially the same height of the bottom surface of the first recess region 124. As a result, the upper surface of the single-crystalline semiconductor plug 130 may become recessed to the depth of the first recess region 124 and the recessed upper surface of the single-crystalline semiconductor plug 130 may be exposed to the first recess region 124. In another embodiment, the single-crystalline semiconductor plug 130 is not etched. As a result, a sidewall of the single-crystalline semiconductor plug 130 may be exposed within the first recess region 124.

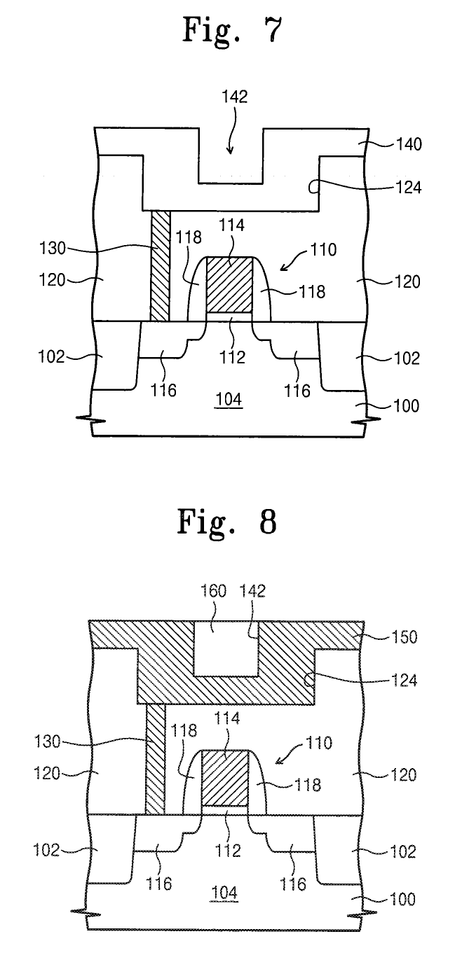

Referring to FIG. 7, a polycrystalline semiconductor layer 140 is formed on the first interlayer insulating layer 120 where the first recess region 124 is formed. The polycrystalline semiconductor layer 140 may, for example, be a polycrystalline silicon layer. In one embodiment, an amorphous semiconductor layer may be formed instead of the polycrystalline semiconductor layer 140. In such an embodiment, the amorphous semiconductor layer may be, for example, an amorphous silicon layer. The polycrystalline semiconductor layer 140 may be conformally formed along an upper surface of the first interlayer insulating layer 120 including the first recess region 124. Accordingly, a surface profile of the polycrystalline semiconductor layer 140 may be substantially consistent with a surface profile of the first interlayer insulating layer 120. As a result, a gap region 142 overlapping the first recess region 124 may be defined by the polycrystalline semiconductor layer 140. A portion of the gap region 142 may be disposed within the first recess region 124.

Referring to FIG. 8, the polycrystalline semiconductor layer 140 is crystallized to form a single-crystalline semiconductor layer 150. In one embodiment, crystallization may be performed by an annealing process. The polycrystalline structure of the polycrystalline semiconductor layer 140 may change to a single-crystalline structure of the single-crystalline semiconductor plug 130 through the annealing process. The single-crystalline semiconductor layer 150 may have substantially the same crystalline structure as the single-crystalline semiconductor plug 130.

As shown in FIG. 8, a sacrificial layer 160 filling the gap region 142 is also formed. In one embodiment, the sacrificial layer 160 is formed on the single-crystalline semiconductor layer 150 by forming an insulating layer filling the gap region 142, followed by planarizing the insulating layer down to an upper surface of the single-crystalline semiconductor layer 150. The sacrificial layer 160 may include a material having an etching selectivity with respect to the single-crystalline semiconductor layer 150 and the first interlayer insulating layer 120. For example, the sacrificial layer 160 may include a nitride material.

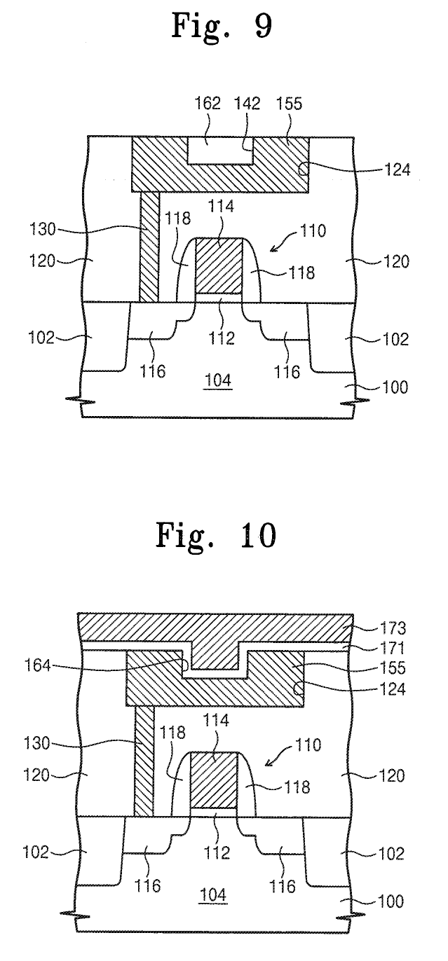

Referring to FIG. 9, the single-crystalline semiconductor layer 150 and the sacrificial layer 160 are etched to form a single-crystalline semiconductor pattern 155 and a sacrificial layer pattern 162 in the first recess region 124. In one embodiment, the single-crystalline semiconductor pattern 155 and the sacrificial layer pattern 162 may be formed by performing a planarization process (e.g., a CMP process) down to an upper surface of the first interlayer insulating layer 120. The single-crystalline semiconductor pattern 155 and the sacrificial layer pattern 162 may have substantially the same height as the first interlayer insulating layer 120 by the planarization process. That is, the upper surface of the single-crystalline semiconductor pattern 155 and the upper surface of the sacrificial layer pattern 162 may be substantially coplanar with the upper surface of the first interlayer insulating layer 120.

Referring to FIG. 10, the sacrificial layer pattern 162 is removed by an etching process and a second recess region 164 is defined by the single-crystalline semiconductor pattern 155. In one embodiment, the second recess region 164 is located at a center region of the single-crystalline semiconductor pattern 155. The location of the second recess region 164 may substantially correspond to location of the previously formed sacrificial layer pattern 162. In the above etching process, a condition, (e.g., an etching gas or an etching solution) that selectively etches the sacrificial layer pattern 162 with respect to the first interlayer insulating layer 120 and the single-crystalline semiconductor pattern 155 may be used.

An insulating layer 171 and a conductive layer 173 are formed on the first interlayer insulating layer 120, on the single-crystalline semiconductor pattern 155 and within the second recess region 164. The insulating layer 171 may be formed of a material such as an oxide using a process such as CVD or thermal oxidation. The conductive layer 173 may be formed of a material such as doped silicon and/or metal using a process such as CVD. The insulating layer 171 may be substantially uniformly formed along the single-crystalline semiconductor pattern 155 and within the second recess region 164. The conductive layer 173 fills the second recess region 164.

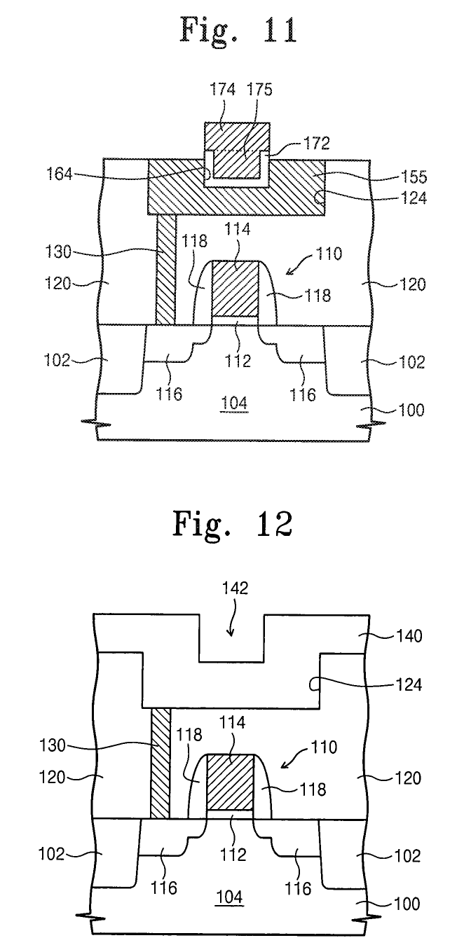

Referring to FIG. 11, the insulating layer 171 and the conductive layer 173 are etched to form a second gate insulating layer 172 and a second gate electrode 174. In one embodiment, the above-mentioned etching process may be performed using two steps. For example, a first step may be performed to etch the conductive layer 173, thereby forming the second gate electrode 174, and a second step may be performed to etch the insulating layer 171, thereby forming the second gate insulating layer 172. In another embodiment, only the first step may be performed and the insulating layer 171 may not be etched. The insulating layer 171 may function as an etching stopper in the first step.

The second gate electrode 174 includes a protrusion 175 that protrudes from an intermediate surface of the second gate electrode 174 over an upper surface of the second gate insulating layer 172 and fills the second recess region 164. The second gate insulating layer 172 may have a “U” shaped configuration and may enclose the protrusion.

In the embodiments exemplarily described above, when the conductive layer 173 is etched to form the second gate electrode 174, the underlying single-crystalline semiconductor pattern 155 is not exposed. As a result, any damage that may be incurred by the single-crystalline semiconductor pattern 155 during formation of the second gate electrode 174 may be reduced or eliminated. Thus, reliability and an operational characteristic of the device may be improved because, for example, an electrical characteristic of the single-crystalline semiconductor pattern 155 may sufficiently correspond to underlying first transistor 110. For example, in the case that the single-crystalline semiconductor pattern 155 is formed of single-crystalline silicon and the conductive layer 173 is formed of polysilicon, if the single-crystalline semiconductor pattern 155 is exposed when the conductive layer 173 is etched, the single-crystalline semiconductor pattern 155 may be damaged by etching because the single-crystalline semiconductor pattern 155 does not have an etching selectivity with respect to the conductive layer 173. In the case that the single-crystalline semiconductor pattern 155 is formed on the first interlayer insulating layer 120 and protrudes above the first interlayer insulating layer 120, a sidewall of the single-crystalline semiconductor pattern 155 that is exposed is damaged during etching of the conductive layer 173. Since etching gas is concentrated on the edge of the single-crystalline semiconductor pattern 155, the etching damage may be more serious. When the conductive layer 173 adjacent to both sides of the single-crystalline semiconductor pattern 155 is etched, the insulating layer 171 on the single-crystalline semiconductor pattern 155 may be etched and an upper surface of the single-crystalline semiconductor pattern 155 may be damaged due to a step difference between the single-crystalline semiconductor pattern 155 and the first interlayer insulating layer 120.

Referring back to FIG. 1, second spacers 178 are formed on sidewalls of the second gate electrode 174 and second impurity regions 176 are formed in the single-crystalline semiconductor pattern 155 adjacent to both sides of the second gate electrode 174. In one embodiment, the second spacers 178 may be formed by forming an insulating layer including a material such as silicon nitride on the single-crystalline semiconductor pattern 155, the second gate electrode 174 and the first interlayer insulating layer 120, followed by anisotropically etching the insulating layer. The second impurity regions 176 may be formed to have a lightly doped drain (LDD) structure or a double diffused drain (DDD) structure by performing an ion implantation process twice. For example, a first ion implantation process may be performed to form low concentration impurity regions before the second spacers 178 are formed and a second ion implantation process may be performed after the second spacers 178 are formed to form high concentration impurity regions. The second gate electrode 174 and the second impurity regions 176 constitute the second transistor 170. A second interlayer insulating layer 180 covering the second transistor 170 is then formed on the first interlayer insulating layer 120. The second interlayer insulating layer 180 may be formed of a material such as oxide using a process such as chemical vapor deposition (CVD).

Referring to FIGS. 12 to 14, a method of forming a laminated semiconductor device of FIG. 1, in accordance with another embodiment of the present invention will be described. Many features of the method described with respect to FIGS. 12 to 14 are similar to those described above with respect to FIGS. 1 and 3-11. Therefore, a detailed description of such features will be omitted.

Referring to FIG. 12, a polycrystalline semiconductor layer 140 is formed on the first interlayer insulating layer 120 and within the first recess region 124. The polycrystalline semiconductor layer 140 may be a polycrystalline silicon layer. In another embodiment, an amorphous semiconductor layer may be formed instead of the polycrystalline semiconductor layer 140. In such an embodiment, the amorphous semiconductor layer may be an amorphous silicon layer. The polycrystalline semiconductor layer 140 may be conformally formed along an upper surface of the first interlayer insulating layer 120 including the first recess region 124. Accordingly, a surface profile of the polycrystalline semiconductor layer 140 may be substantially consistent with a surface profile of the first interlayer insulating layer 120. As a result, a gap region 142 overlapping the first recess region 124 may be defined.

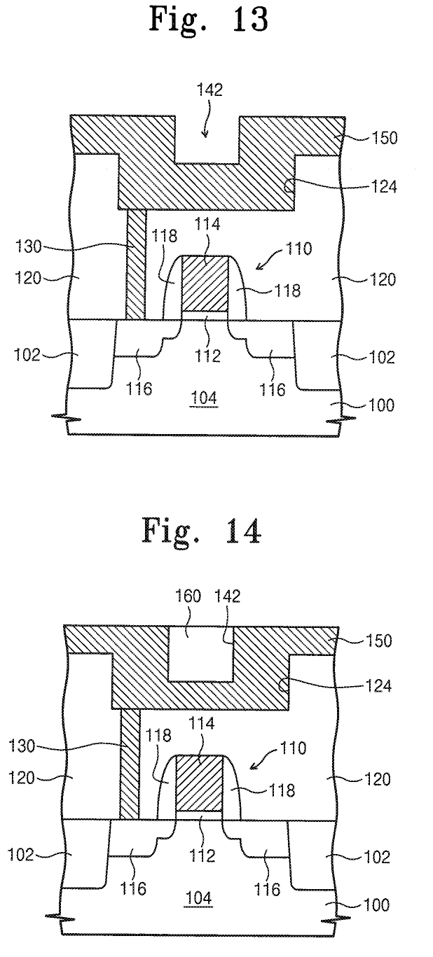

Referring to FIG. 13, the polycrystalline semiconductor layer 140 is crystallized to form a single-crystalline semiconductor layer 150. In one embodiment, crystallization may be performed by an annealing process. The polycrystalline structure of the polycrystalline semiconductor layer 140 may change to a single-crystalline structure of the single-crystalline semiconductor plug 130 through the annealing process. The single-crystalline semiconductor layer 150 may have substantially the same structure as the single-crystalline semiconductor plug 130.

Referring to FIG. 14, the single-crystalline semiconductor layer 150 is anisotropically etched. As a result, an upper surface of the single-crystalline semiconductor layer 150 becomes recessed and a lower region of the gap region 142 is recessed to be disposed within the first recess region 124.

Next, a sacrificial layer 160 filling the gap region 142 is formed. In one embodiment, the sacrificial layer 160 may be formed by forming an insulating layer filling the gap region 142, followed by planarizing the insulating layer down to the upper surface of the single-crystalline semiconductor layer 150. The sacrificial layer 160 may include a material having an etching selectivity with respect to the single-crystalline semiconductor layer 150 and the first interlayer insulating layer 120. For example, the sacrificial layer 160 may include a nitride material.

As described above, a portion of the gap region 142 is disposed within the first recess region 124 by anisotropically etching the single-crystalline semiconductor layer 150. Thus, a sacrificial layer pattern 162 may be easily formed as described above with respect to FIG. 9. In addition, a second recess region 164 defined by the single-crystalline semiconductor pattern 155 may be easily formed by removing the sacrificial layer pattern 162 as described above with respect to FIG. 10. It will be appreciated that formation of the laminated semiconductor device according to the present embodiment may be completed using the same method as the aforementioned embodiments.

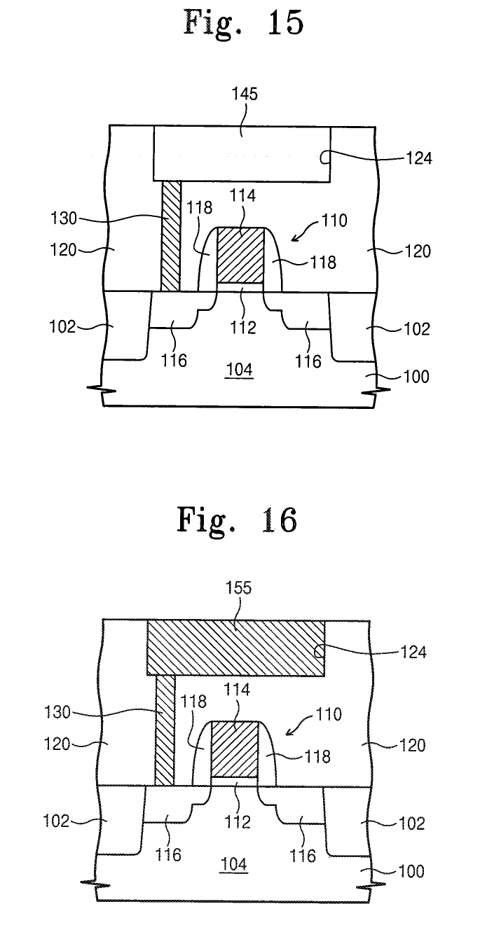

Referring to FIGS. 15 to 19, a method of forming a laminated semiconductor device of FIG. 1, in accordance with still another embodiment of the present invention will be described. Many features of the method described with respect to FIGS. 15 to 19 are similar to those described above with respect to FIGS. 1 and 3-11. Therefore, a detailed description of such features will be omitted.

Referring to FIG. 15, a polycrystalline semiconductor pattern 145 is formed in the first recess region 124, which is formed in an upper portion of the first interlayer insulating layer 120. The polycrystalline semiconductor pattern 145 may be a polycrystalline silicon pattern. In another embodiment, an amorphous semiconductor pattern may be formed instead of the polycrystalline semiconductor pattern 145. In such an embodiment, the amorphous semiconductor pattern may be an amorphous silicon pattern. In one embodiment, the polycrystalline semiconductor pattern 145 may be formed by forming the polycrystalline semiconductor layer 140 on the first interlayer insulating layer 120 (see, e.g., FIG. 7) to fill the first recess region 124, followed by performing a planarization process (e.g., a CMP process) down to an upper surface of the first interlayer insulating layer 120.

Referring to FIG. 16, the polycrystalline semiconductor pattern 145 is crystallized to form a single-crystalline semiconductor pattern 155. In one embodiment, crystallization may be performed by an annealing process. The polycrystalline structure of the polycrystalline semiconductor pattern 145 may change to a single-crystalline structure of the single-crystalline semiconductor plug 130 through the annealing process. The single-crystalline semiconductor pattern 155 may have substantially the same structure as the single-crystalline semiconductor plug 130.

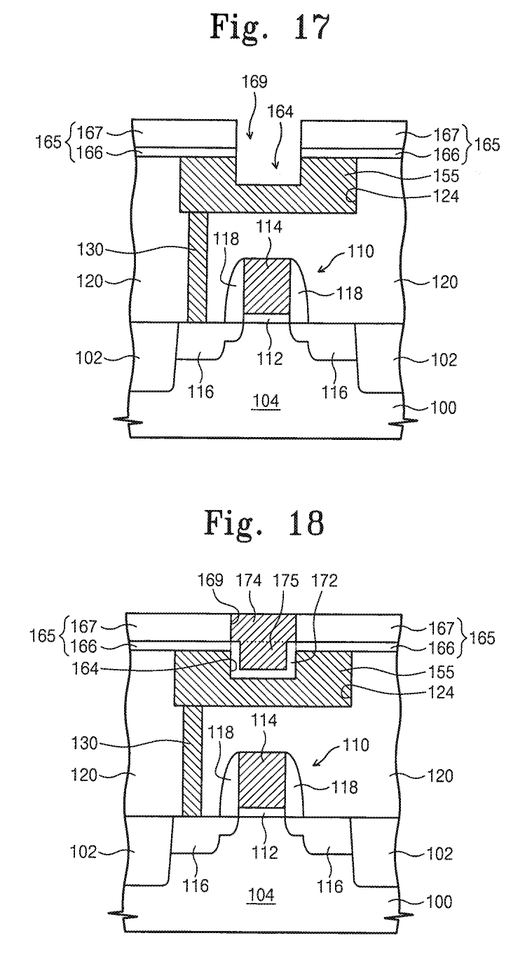

Referring to FIG. 17, a mask pattern 165 exposing a portion of the single-crystalline semiconductor pattern 155 is formed on the first interlayer insulating layer 120. In one embodiment, the mask pattern 165 may expose a center portion of the single-crystalline semiconductor pattern 155. In one embodiment, the mask pattern 165 may, for example, include an oxide layer pattern 166 and a nitride layer pattern 167. The mask pattern 165 may include a line shaped opening 169 exposing the single-crystalline semiconductor pattern 155. The single-crystalline semiconductor pattern 155 is etched using the mask pattern 165 as an etching mask to define a second recess region 164. In the above etching process, a condition that selectively etches the single-crystalline semiconductor pattern 155 with respect to the first interlayer insulating layer 120 may be used.

Referring to FIG. 18, a second gate insulating layer 172 is formed on the single-crystalline semiconductor pattern 155 and within the second recess region 164. The second gate insulating layer 172 may be formed along a profile of the second recess region 164. The second gate insulating layer 172 may be formed of a material such as oxide using a process such as thermal oxidation. A second gate electrode 174 that fills the second recess region 164 and the line shaped opening 169 is formed on the second gate insulating layer 172. In one embodiment, the second gate electrode 174 may be formed by forming a conductive layer including doped polycrystalline silicon and/or metal on the second gate insulating layer 172, followed by performing a planarization process down to an upper surface of the mask pattern 165. In one embodiment, the conductive layer may be formed using a process such as CVD. The second gate electrode 174 includes a protrusion 175 that fills the second recess region 164.

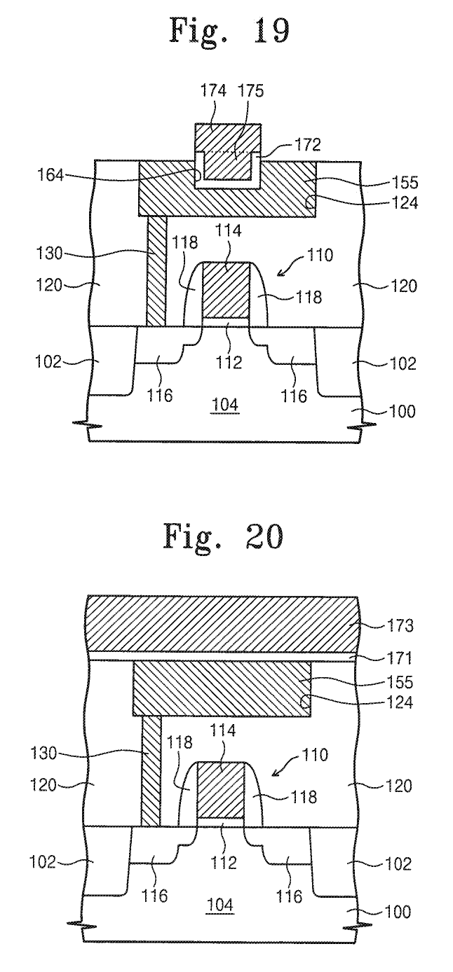

Referring to FIG. 19, an etching process is performed to remove the mask pattern 165. It will be appreciated that formation of the laminated semiconductor device according to the present embodiment may be completed using the same method as the aforementioned embodiments.

As described above, the second gate electrode 174 is formed using a damascene technique. As a result, any etching damage that may be incurred by the single-crystalline semiconductor pattern 155 during formation of the second gate electrode 174 may be reduced or eliminated. Thus, reliability and an operational characteristic of the device may be improved because, for example, an electrical characteristic of the single-crystalline semiconductor pattern 155 may sufficiently correspond to underlying first transistor 110.

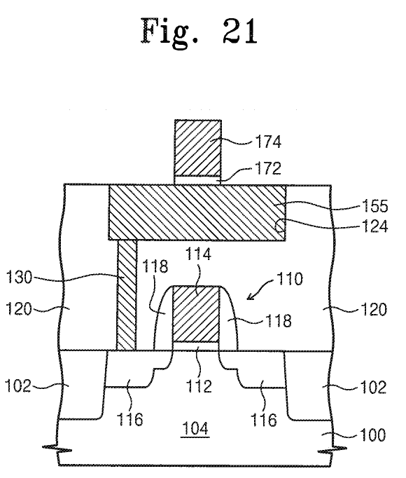

Referring to FIGS. 20 and 21, a method of forming the laminated semiconductor device of FIG. 2, in accordance with one embodiment will be described. Many features of the method described with respect to FIGS. 20 and 21 are similar to those described above with respect to the aforementioned embodiments. Therefore, a detailed description of such features will be omitted.

Referring to FIG. 20, an insulating layer 171 and a conductive layer 173 are formed on the first interlayer insulating layer 120 including a single-crystalline semiconductor pattern 155 (see, e.g., FIG. 16). In one embodiment, the insulating layer 171 may be formed of a material such as oxide using a process such as thermal oxidation, CVD, or the like. In one embodiment, the conductive layer 173 may be formed of a material such as doped polycrystalline silicon and/or metal using a process such as CVD.

Referring to FIG. 21, the insulating layer 171 and the conductive layer 173 are etched to form a second gate insulating layer 172 and a second gate electrode 174. The second gate insulating layer 172 and the second gate electrode 174 may be formed using the same method as the method of forming the first gate insulating layer 112 and the first gate electrode 114.

Referring back to FIG. 2, the second spacers 178 are formed on both sidewalls of the second gate electrode 174 and the second impurity regions 176 are formed in the single-crystalline semiconductor pattern 155 adjacent to both sides of the second gate electrode 174. In one embodiment, the second spacers 178 may be formed by forming an insulating layer including a material such as silicon nitride on the single-crystalline semiconductor pattern 155, the second gate electrode 174 and the first interlayer insulating layer 120, followed by anisotropically etching the insulating layer. The second impurity regions 176 may be formed to have a lightly doped drain (LDD) structure or a double diffused drain (DDD) structure by performing an ion implantation process twice. For example, a first ion implantation process may be performed to form low concentration impurity regions before the second spacers 178 are formed and a second ion implantation process may be performed after the second spacers 178 are formed to form high concentration impurity regions. The second gate electrode 174 and the second impurity regions 176 constitute the second transistor 170. The second interlayer insulating layer 180 covering the second transistor 170 is then formed on the first interlayer insulating layer 120. The second interlayer insulating layer 180 may be formed of a material such as oxide using a process such as CVD. When the conductive layer is etched to form the second gate electrode 174, the single-crystalline semiconductor pattern 155 is not damaged by an etching. Thus, the semiconductor device can be stably formed.

It will be appreciated that the embodiments of the present invention can be practiced in many ways. The paragraphs below provide a non-limiting of some exemplary embodiments of the present invention.

One embodiment exemplarily described herein can be generally described as a method of forming a semiconductor device that includes forming a first transistor on a semiconductor substrate, forming an interlayer insulating layer over the first transistor on the semiconductor substrate, forming a single-crystalline semiconductor plug connected to the semiconductor substrate in the interlayer insulating layer, etching the interlayer insulating layer to form a first recess region exposing the single-crystalline semiconductor plug, forming a single-crystalline semiconductor pattern connected to the single-crystalline semiconductor plug in the first recess region, and forming a second transistor on the single-crystalline semiconductor pattern.

In one embodiment, an upper surface of the single-crystalline semiconductor pattern may be substantially coplanar with, or lower than, an upper surface of the interlayer insulating layer.

In one embodiment, the single-crystalline semiconductor pattern may include a second recess region.

In one embodiment, the second transistor may be formed according to a process that includes forming a gate electrode within the second recess region.

In one embodiment, the single-crystalline semiconductor pattern may be formed according to a process that includes forming an amorphous or polycrystalline semiconductor layer within the first recess region, crystallizing the semiconductor layer to form a single-crystalline semiconductor layer, and etching the single-crystalline semiconductor layer to expose an upper surface of the interlayer insulating layer.

In one embodiment, the semiconductor layer may be formed conformally along a surface of the first recess region. A gap region overlapping the first recess region may be defined by the semiconductor layer.

In one embodiment, a sacrificial layer filling the gap region may be formed before etching the single-crystalline semiconductor layer, forming a sacrificial layer filling the gap region.

In one embodiment, the single-crystalline semiconductor layer may be anisotropically etched before forming the sacrificial layer such that a portion of the gap region is disposed within the first recess region.

In one embodiment, the single-crystalline semiconductor layer may be etched by a process that includes etching the sacrificial layer to form a sacrificial layer pattern contacting the single-crystalline semiconductor pattern in the first recess region. The method may further include removing the sacrificial layer pattern before forming the second transistor.

In one embodiment, the single-crystalline semiconductor pattern may be formed by a process that includes forming an amorphous or polycrystalline semiconductor pattern within the first recess region and crystallizing the semiconductor pattern.

In one embodiment, the method may further include, after forming the single-crystalline semiconductor pattern, a mask pattern may be formed that exposes a portion of the single-crystalline semiconductor pattern. An etching process may be performed using the mask pattern as an etching mask to form a second recess region in the exposed single-crystalline semiconductor pattern.

In one embodiment, the second transistor may be formed by a process that includes forming a gate insulating layer on the single-crystalline semiconductor pattern within the second recess region, forming a gate electrode on the gate insulating layer, and removing the mask pattern.

In one embodiment, the first transistor may include an impurity region disposed in the semiconductor substrate. Accordingly, the single-crystalline semiconductor plug may be formed by a process that includes etching the interlayer insulating layer to form an opening exposing the impurity region and performing an epitaxial growth process on the impurity region of the exposed first transistor.

Although embodiments of the present invention have been exemplarily described in connection with the accompanying drawings, the embodiments are not limited thereto. It will be apparent to those skilled in the art that various substitutions, modifications and changes may be made without departing from the scope and spirit of the invention.

What is claimed is:

1. A semiconductor device, comprising:
a first transistor on a semiconductor substrate;
a first interlayer insulating layer covering the first transistor and including a first recess region;
a single-crystalline semiconductor pattern disposed in the first recess region;
a single-crystalline semiconductor plug connecting the semiconductor substrate to the single-crystalline semiconductor pattern; and
a second transistor on the single-crystalline semiconductor pattern.

2. The device of claim 1, wherein the single-crystalline semiconductor plug is disposed in the first interlayer insulating layer.

3. The device of claim 1, wherein an upper surface of the single-crystalline semiconductor pattern is substantially coplanar with, or lower than, an upper surface of the first interlayer insulating layer.

4. The device of claim 1, wherein the single-crystalline semiconductor pattern includes a second recess region.

5. The device of claim 4, wherein a portion of the gate electrode of the second transistor is disposed within the second recess region.

6. The device of claim 1, wherein
the first transistor includes an impurity region disposed in the semiconductor substrate, and
the single-crystalline semiconductor plug is epitaxially grown from the impurity region.

7. The device of claim 1, wherein a crystalline structure of the single-crystalline semiconductor plug is substantially the same crystalline structure as the single-crystalline semiconductor pattern.

8. The device of claim 1, further comprising a second interlayer insulating layer over the second transistor on the first interlayer insulating layer,
wherein an interface between the first interlayer insulating layer and the second interlayer insulating layer is substantially coplanar with an upper surface of the single-crystalline semiconductor pattern.

9. The device of claim 1, wherein the single-crystalline semiconductor plug electrically connects the single-crystalline semiconductor pattern to the first transistor.

10. The device of claim 1, wherein the single-crystalline semiconductor pattern comprises silicon.

11. The device of claim 1, wherein the single-crystalline semiconductor plug comprises silicon.

12. A semiconductor device, comprising:
a first transistor on a semiconductor substrate, wherein the first transistor includes a first impurity region disposed in the semiconductor substrate;
an interlayer insulating layer covering the first transistor;
a plug disposed in the interlayer insulating layer, wherein a first end portion of the plug contacts the first impurity region;
a single-crystalline semiconductor pattern contacting a second end portion of the plug, wherein at least a portion of the single-crystalline semiconductor pattern is below an upper surface of the interlayer insulating layer; and
a second transistor on the single-crystalline semiconductor pattern, wherein the first transistor includes a first impurity region disposed in the single-crystalline semiconductor pattern.

13. The device of claim 12, wherein the interlayer insulating layer includes a recess region defined therein and the single-crystalline semiconductor pattern is disposed in the recess region.

14. The device of claim 12, wherein the plug comprises a single-crystalline semiconductor material.
